(19) United States
(12) Patent Application Publication
(10) Pub. No.: US 2012/0167937 A1
(43) Pub. Date: Jul. 5, 2012

(54) THERMOELECTRIC MODULE AND METHOD OF MANUFACTURING THE SAME

(76) Inventors: Yuan-Chang Fann, Zhudong Township (TW); Chun-Mu Chen, Hsinchu City (TW); Hsu-Shen Chu, Hsinchu City (TW); Cheng-Chuan Wang, Yongjing Township (TW); Jenn-Dong Hwang, Hsinchu City (TW)

(21) Appl. No.: 13/195,299

(22) Filed: Aug. 1, 2011

(30) Foreign Application Priority Data
Dec. 29, 2010 (TW) 99146678

(51) Int. Cl. H01L 35/30; H01L 35/34; H01L 35/04

(52) U.S. Cl. 136/224; 136/230; 29/879; 29/884; 136/201

(57) ABSTRACT

A thermoelectric module includes a first and a second substrates, plural thermoelectric elements, plural first and second metal electrodes, plural first and second solder layers, and spacers. The thermoelectric elements are disposed between the first and second substrates, and each pair includes a P-type and an N-type thermoelectric elements. An N-type thermoelectric element is electrically connected to the other P-type thermoelectric element of the adjacent pair of thermoelectric element by the second metal electrode. The first metal electrodes and the lower end surfaces of the P/N type thermoelectric elements are jointed by the first solder layers. The second metal electrodes and the upper end surfaces of the P/N type thermoelectric elements are jointed by the second solder layers. The spacers are positioned at one of the first and second solder layers. The melting point of the spacer is higher than the liquidus temperatures of the first and second solder layers.

This application claims the benefit of Taiwan application Serial No. 099146678, filed Dec. 29, 2010, the subject matter of which is incorporated herein by reference.

### BACKGROUND OF THE DISCLOSURE

1. Field of the Disclosure

The disclosure relates in general to a thermoelectric module and method of manufacturing the same, and more particularly to a thermoelectric module operable stably at over temperature and method of manufacturing the same.

2. Description of the Related Art

The thermoelectric module, able to operate as a heat pump, has been widely employed in precise temperature control unit. Besides, the thermoelectric module is also used to be a power generator through converting the temperature difference ΔT of hot end temperature (Th) and cold end temperature (Tc) of the module into electricity. The converting efficiency η is predominantly decided by the product (ZT) of thermoelectric figure of merit (Z) of the thermoelectric elements and temperature (T), and also decided by the temperature difference ΔT across the module. The temperature difference ΔT sets the upper limit of efficiency through the Carnot efficiency, η_{c}=ΔT/Th. The ZT of the thermoelectric elements influences how close the converting efficiency η to approach the upper limit of carnot cycle, μ_{c}, through the thermoelectric figure of merit, Z, defined by α²·σ/κ, where α is the seebeck coefficient of the thermoelectric elements, σ is the electric conductivity of the thermoelectric elements, κ is the thermal conductivity of the thermoelectric elements, which all vary with temperature.

Since the ZT values of almost thermoelectric materials are below 2 so far and all vary with temperature, it is impossible to achieve high convert efficiency of a module by using homogeneous thermoelectric elements under large temperature differences. Therefore, processes of segmenting a homogeneous thermoelectric material with high ZT at specific temperature and another homogeneous thermoelectric material with high ZT at higher temperature, and even two-stage thermoelectric devices have been proposed to be developed, in order to increase the converting efficiency above. In order to increase the converting efficiency or the generation output of the thermoelectric module, high temperature difference ΔT is the necessarily operation condition, no matter for the traditional one-stage thermoelectric module or the two-stage thermoelectric module, even the thermoelectric module comprising the segmented thermoelectric elements. However, large temperature difference operation may lead to higher degree thermal expansion mismatch inside the thermoelectric device or cause the melting of bonding layers between the thermoelectric elements and the metal electrodes occasionally. Although some high-temperature welding alloys such as SnTe, Sn—Te—Bi, Cu—In, or Cu—Sb and corresponding welding processes could be chosen to overcome the latter problem, the thermoelectric figure of merit of thermoelectric elements could be deteriorated because of the high-temperature bonding processes usually. The most common and easily applied for industrial bonding process on thermoelectric module is solder reflowing, but the industrial solders hardly withstand service temperature over 300° C. It is very likely either the thermoelectric elements falls down in case of liquid-phase solder squeezing out, thus destroying the thermoelectric device, or the liquid-phase of solder melt overflows to adjacent metal electrodes, thereby decreasing the converting efficiency of the thermoelectric module.

A thermoelectric generator is built to withstand and operate with condition of high temperature difference or momentary over-temperature fluctuations ideally, but the welded structure composed of thermoelectric elements and metal electrodes definitely experiences a thermal stress caused by the influence of thermal expansion mismatches, this may cause a de-bonding of welded structure or splitting failure of the thermoelectric elements. In practice, the thicker the solder layers bonding the thermoelectric elements and the corresponding solder layers are and the softer the solder layers are, the easier the solder layers deform, so as to accommodate the thermal stress described above. Although it is easier to adjust the thermal stress of a thermoelectric device by partially melting and thus softening the thick solder layers under over-temperature condition, the melted solder liquid could be extruded out, thereby causing the short circuit due to overflow of the melted solder liquid. This would lead to the dramatic drop of the converting efficiency of the thermoelectric generator.

U.S. Pat. No. 7,278,199 provides a method of manufacturing thermoelectric module to overcome the thermal stress problem of the thermoelectric module. The junction surface between the electrodes on direct bond copper substrate and the cold side of multi-pair electrically series connection P-type and N-type thermoelectric elements is welded by solder layers, but the junction between the hot side of the thermoelectric elements and the electrodes use sliding contact mode. Although using the sliding contact mode has function of adjusting thermal stress, the contact resistance of the hot side interface raises and thus series circuit resistance increases. Besides, US patent publication No. US2010/0101620 provides a thermoelectric module structure having micron-sized protrusions grown on electrode surfaces. The fine conical protrusions are applied to disperse the heat passing through the thermoelectric elements and thus to lower the temperature difference between the substrate and the thermoelectric elements. However, the height of the protrusions is only a few microns and is much smaller than the solder layers thickness of general thermoelectric generators. Therefore, the thermoelectric module comprising the above protrusions must operate at hot side temperature below the melting point of solder layers inside, or else the electrode surfaces modified with the micron-sized protrusions can hardly stop the overflow of massive melt solder.

FIG. 1 is a schematic diagram of a traditional thermoelectric module comprising two direct bond metal ceramic substrates 110. Each direct bond metal ceramic substrate 110 includes a ceramic plate 112 and several metal electrodes 114 covering on the surface of the ceramic plate 112 directly. The metal electrodes 114 may be a metal conductive layer printed on the surface of the ceramic plate 112, or a metal plate soldered on the surface of the ceramic plate 112. The surface of the metal electrodes 114 are usually processed by coating layer (not shown) which has diffusion barrier function. In FIG. 1, the solder layers 120 are disposed respectively between the direct bond metal ceramic substrate 110 and the P-type thermoelectric elements 142 or the N-type thermoelectric elements 144 to join the P-type and the N-type thermoelectric elements disposed alternately and the metal electrodes 114 to make the P-type and the N-type thermoelectric elements (142 and 144) to present electrically series connection to each other.

Additionally, when manufacturing the thermoelectric module 100 in FIG. 1, the thickness 126 of the solder layer 120 is not easy to be adjusted and controlled, this limits the reliability of the thermoelectric module 100. When using the thermoelectric module 100 for power generation, the solder layers 120 of the hot end may be overheated to melt, and then squeezed out by the clamp pressure of the thermoelectric module 100. Thus, the interface thickness 126 decreases dramatically to cause the failure of the thermoelectric elements. The problems described above result in the concern of reliability with the working life of the thermoelectric module.

To sum up, the high temperature difference operation condition is a necessity to increase the converting efficiency or generation output of the thermoelectric device. Thus, it is desired to provide a thermoelectric module which not only the thickness thereof is easily controlled in the manufacturing process, but also has the capability of stabilizing the minimum thickness of the solder layers even the solder layers are partially melting during momentary over-temperature operation.

### SUMMARY OF THE DISCLOSURE

The disclosure is directed to a thermoelectric module having a plurality of spacers joined with the solder layers and method of manufacturing the same. The spacers are mainly disposed between the metal electrodes and the thermoelectric elements of the thermoelectric module. The melting point of the spacers is higher than the liquidus temperature of the solder layers, thus the thickness stability of solder layers between the metal electrode and the thermoelectric element could be maintained, thereby not only improving yield of manufacturing the thermoelectric module but also improving the operation reliability of the thermoelectric module.

According to a first aspect of the present disclosure, a thermoelectric module is provided. The thermoelectric module comprises a first substrate, a second substrate, a plurality of P-type and N-type thermoelectric elements, a plurality of first metal electrodes, a plurality of first solder layers, a plurality of second metal electrodes, a plurality of second solder layers and a plurality of spacers.

The first substrate and the second substrate are disposed opposite to each other.

The thermoelectric elements comprise P-type and N-type thermoelectric elements. Each of the thermoelectric elements has an upper end surface and a lower end surface and is disposed between the first substrate and the second substrate. The P-type and the N-type thermoelectric elements are disposed alternately.

The first metal electrodes are disposed between the first substrate and the lower end surfaces of the P-type and the N-type thermoelectric elements for electrically connecting to each of the thermoelectric elements respectively or electrically connecting to the adjacent P-type thermoelectric element and the N-type thermoelectric element.

The first solder layers are for joining the first metal electrodes and the lower end surfaces of the P-type and the N-type thermoelectric elements respectively.

The second metal electrodes are disposed between the second substrate and the upper end surfaces of the P-type and the N-type thermoelectric elements for electrically connecting to each of the thermoelectric elements or electrically connecting to the adjacent P-type thermoelectric element and the N-type thermoelectric elements respectively.

The second solder layers are for joining the second metal electrodes and the upper end surfaces of the P-type and the N-type thermoelectric elements respectively.

The spacer is at least disposed at and contacting one of the first solder layers and the second solder layers. The melting point of the spacer is higher than the liquidus temperature of at least one of the first solder layers and the second solder layers contacting the spacer.

According to a second aspect of the present disclosure, a method of manufacturing a thermoelectric module is provided. First, a first substrate, a second substrate, a plurality of P-type thermoelectric elements and a plurality of N-type thermoelectric elements are provided. Each of the thermoelectric elements has an upper end surface and a lower end surface.

A plurality of first and second metal electrodes are provided. There is at least one spacer at a surface of one of the end surfaces of at least one of the first and the second metal electrodes. The one of the end surfaces points to the thermoelectric elements.

The first and the second metal electrodes are disposed between the first substrate and the second substrate. The P-type and N-type thermoelectric elements are disposed alternately and between the first and the second metal electrodes. The lower faces of the thermoelectric elements are connected to the first metal electrodes while the upper faces of the thermoelectric elements are connected to the second metal electrodes.

A plurality of first solder plates are provided on the surfaces of the first metal electrodes and a plurality of the second solder plates are provided on the surfaces of the second metal electrodes. The spacer is contacted at least one solder plate of the first and the second solder plates wherein the melting point of the spacer is higher than the liquidus temperature of the first and the second solder layers.

The first substrate, the first metal electrodes, the P-type thermoelectric elements, the N-type thermoelectric elements, the second metal electrodes and the second substrate are assembled by reflow process to make the first solder plates form the first solder layers and join the first metal electrodes and a plurality of lower end surfaces of the P-type and the N-type thermoelectric elements, and to make the second solder plates form the second solder layers and join the second metal electrodes and a plurality of upper end surfaces of the P-type and the N-type thermoelectric elements.

According to a third aspect of the present disclosure, another method of manufacturing a thermoelectric module is further provided. First, a first substrate, a second substrate, a plurality of P-type thermoelectric elements and a plurality of N-type thermoelectric elements, a plurality of first and second metal electrodes, a paste solder and a plurality of granulated spacers are provided. Each of the thermoelectric elements has an upper end surface and a lower end surface. The melting point of the granulated spacers is higher than the liquidus temperature of the metallized solder after reflowing.

The granulated spacers are mixed with the paste solder.

The paste solder mixed with the granulated spacers is coated on the surface of at least one of the first and/or the second metal electrodes for forming the first solder layers and the second solder layers after subsequent reflow assembly.

The first and the second metal electrodes are disposed between the first substrate and the second substrate. The P-type and N-type thermoelectric elements are disposed alternately and between the first and the second metal electrodes. The lower faces of the thermoelectric elements are connected to the first metal electrodes while the upper faces of the thermoelectric elements are connected to the second metal electrodes.

The first substrate, the first metal electrodes, the P-type thermoelectric elements, the N-type thermoelectric elements, the second metal electrodes and the second substrate are assembled by reflow process to make the first solder layers spread the granulated spacers therein join the first metal electrodes and the lower end surfaces of the P-type and the N-type thermoelectric elements, and/or to make the second solder layers spread the granulated spacers therein join the second metal electrodes and the upper end surfaces of the P-type and the N-type thermoelectric elements.

The above and other aspects of the disclosure will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic view showing a conventional thermoelectric module.

FIG. 2 is a schematic view showing a thermoelectric module according to a first embodiment of the disclosure.

FIG. 3A to FIG. 3F are schematic views showing first to sixth strip-shaped spacers combination type of the thermoelectric module according to a first embodiment of the disclosure.

FIG. 4 is a schematic view showing a thermoelectric module according to a second embodiment of the disclosure.

FIG. 5 is a schematic view showing another thermoelectric module according to a second embodiment of the disclosure.

FIG. 6A is a schematic view showing a combination type of the granulated spacers and the metal electrodes of the thermoelectric module according to a second embodiment of the disclosure.

FIG. 6B is a schematic view showing another combination type of the granulated spacers and the metal electrodes of the thermoelectric module according to a second embodiment of the disclosure.

FIG. 7 is a schematic view showing a combination type of the spacers and the metal electrodes of the thermoelectric module according to another embodiment of the disclosure.

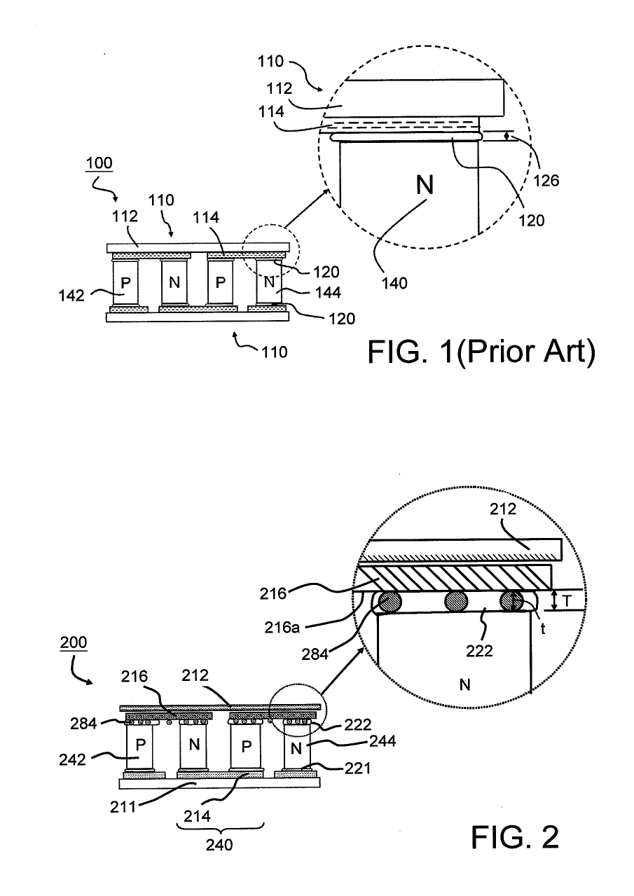

### DETAILED DESCRIPTION OF THE DISCLOSURE

The thermoelectric module disclosed according to the embodiment mainly includes a plurality of spacer disposed in the solder layer between the metal electrodes and the thermoelectric elements. The melting point of the spacer is higher than the liquidus temperature of the solder layer. Even the solder layer be melted because of high temperature in the thermoelectric module in operation, at least the minimum thickness of the solder layer could be maintained and prevent large amounts of melted solder from being squeezed out of the junction interface in the supporting effects of the spacers within the solder layer, so as to improve the operation reliability of the thermoelectric module. The shape of the spacers is not limited, and may be a single shape or a combination of different shapes. Examples of the spacers include strip-shaped spacers, granulated spacers, and other shaped spacers.

The first and second embodiments are provided as following to describe the disclosure, but not to limit the disclosure. In the first embodiment, the spacers are strip-shaped spacers as example. In the second embodiment, the spacers are granulated spacers as example.

### First Embodiment

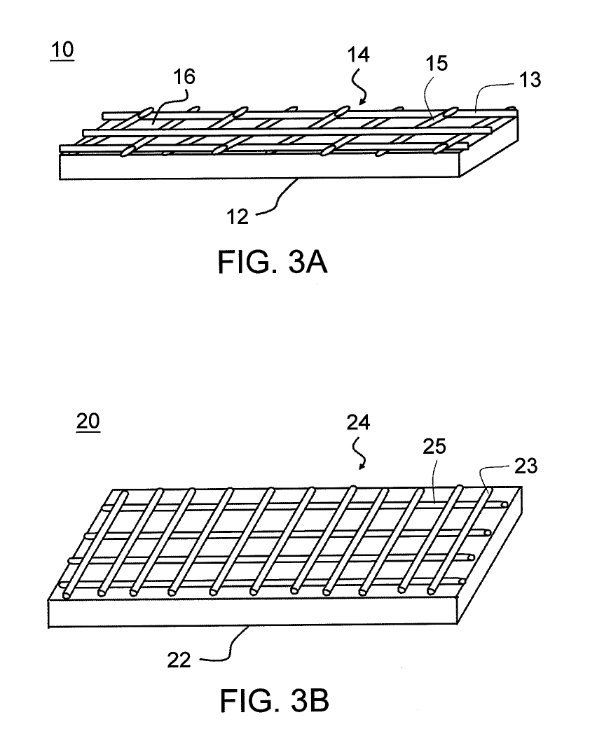

FIG. 2 is a schematic view showing a thermoelectric module according to a first embodiment of the disclosure. The thermoelectric module 200 includes a first substrate 211 and a second substrate 212 disposed to each other, several P-type thermoelectric elements 242 and N-type thermoelectric elements 244, several first metal electrodes 214 and second metal electrodes 216, several first solder layers 221 and second solder layers 222 and spacers. In this embodiment, the strip-shaped spacers 284 are implemented.

Several pairs of the thermoelectric elements 240 are disposed between the first substrate 211 and the second substrate 212. Each pair of the thermoelectric elements 240 includes a P-type thermoelectric element 242 and a N-type thermoelectric element 244 which are electrically connected to each other. The N-type thermoelectric elements 244 of each pair of the thermoelectric elements are electrically connected to adjacent P-type thermoelectric elements 242 of each pair of the thermoelectric elements. The several first metal electrodes 214 are disposed between the first substrate 211 and the lower end surfaces of the P-type thermoelectric elements 242 and the N-type thermoelectric elements 244 to electrically connect to the P-type thermoelectric elements 242 and the N-type thermoelectric elements 244 of each part of the thermoelectric element respectively. Several second metal electrodes 216 are disposed between the second substrate 212 and the upper end surfaces of the P-type thermoelectric elements 242 and the N-type thermoelectric elements 244 to electrically connect to P-type thermoelectric elements 242 and N-type thermoelectric elements 244 of adjacent two pairs of the thermoelectric elements, a P-type thermoelectric element 242 and a N-type thermoelectric element 244 of adjacent one pair of thermoelectric element 240, and a N-type thermoelectric element 244 and a P-type thermoelectric element 242 of adjacent one pair of thermoelectric element 240 to make the P-type thermoelectric elements 242 and the N-type thermoelectric elements 244 electrically series connect to each other.

Furthermore, the first solder layer (such as solder layer) 221 is melted and joined to the first metal electrodes 214 and the lower end surfaces of the P-type thermoelectric elements 242 and N-type thermoelectric elements 244. The second solder layer (such as solder layer) 222 is melted and joined to the second metal electrodes 216 and the upper end surfaces of the P-type thermoelectric elements 242 and N-type thermoelectric elements 244.

In the embodiment, the strip-shaped spacers 284 are disposed in and contacted with the second solder layer 222. The melting point of the strip-shaped spacer 284 is higher than the liquidus temperature of the material of second solder layer 222 contacting the spacers 248. In a manufacturing procedure, the strip-shaped spacers 284 could be disposed on the surface 216a of the second metal electrodes 216 and contact with the second solder layer 222. In an embodiment, the height of the strip-shaped spacer 284 is in a range of about 50% to 100% of the thickness of the second solder layer 222, while the height of the strip-shaped spacers is in a range of about 15 μm to about 500 μm. Thus, the strip-shaped spacers 284 would contact with the upper end surfaces of the P-type thermoelectric elements 242 and the N-type thermoelectric element 244, and the contacting part could be, for example, exposed outside the second solder layer 222.

Although only the second solder layer 222 contains the strip-shaped spacers 284 as illustrated in FIG. 2, the disclosure is not limit thereto. In another embodiment, the strip-shaped spacers 284 may also be disposed in the first solder layer 221 as well as in the second solder layer 222.

The first substrate 211 and the second substrate 212, for example, are a ceramic plate and an insulative sheet material with high thermal conductivity, respectively. The ceramic plate and the first metal electrode 214 directly attached on the surface of the ceramic plate (i.e. the first substrate 211) are generally called direct covered metal ceramic plate. The insulative sheet material (i.e. the second substrate 212) only contacts with the second metal electrode 216 without joining to each other.

The first metal electrode 214 and the second metal electrode 216 are the metal plates made of, for example, copper, aluminum, iron, nickel, cobalt or alloy thereof, or the coated metal plates such as the copper plates coated by nickel, the aluminum plates coated by nickel or the iron plates coated by tin. The strip-shaped spacers 284 are metal wires, for example, steel alloy wires, nickel-chromium alloy wires, nickel wires, nickel-plated aluminum wires or nickel-plated copper wires and so on. In an embodiment, the material of the strip-shaped spacers 284, for example, is selected from the group consisting of iron, cobalt, nickel, chromium, copper, manganese, zirconium, titanium and a combination thereof so as to form reactive intermetallic compounds with liquid tin during reflowing process. The surfaces of the strip-shaped spacers 284 also may be selectively coated by the nickel, silver or tin as the solder top of the spacers.

Moreover, in an embodiment, the strip-shaped spacer 284 may be partially or completely fixed at the second metal electrode 216 by welding, electroplating or coating. The strip-shaped spacers 284 also may be fixed to each other by winding wires. The strip-shaped spacers 284 may be fixed at the second metal electrode 216 by a combination of welding, electroplating, coating and wire-winding.

According to the thermoelectric module 200 provided by the embodiment, the original thickness T of the second solder layer 222 could be adjusted easily by the height t (i.g. the diameter of the wire) of the strip-shaped spacers 284, since the strip-shaped spacer 284 are fixed on the surfaces 216a of the second metal electrode 216. A soft solder layer is easy to be deformed by self-plasticity (functioning like a soft pad). The thicker the thickness T of the second solder layer 222 is, the easier the thermal stress of the thermoelectric module 200 can be adjusted in operation to prevent relatively brittle thermoelectric element from being broken. Besides, with the supporting effects of the strip-shaped spacer 284 in the second solder layer 222, even the solder layer (i.g. the second solder layer 222) on the upper end of the P-type and N-type thermoelectric elements occur fusion during operation, the thickness of the solder layer could still be maintained at a stable thickness, so as to prevent large amounts of fusion solder liquid be squeezed out of the welding surface, thereby improving the operation reliability of the thermoelectric module 200. In other words, when the thermoelectric module 200 is operated, a possible minimum distance between the second solder layer 222 and P-type and N-type thermoelectric elements is determined according to the height t of the strip-shaped spacers 284.

Moreover, three strip-shaped spacers 284 distributed at the second metal electrode 216 on a P-type thermoelectric element 242 or a N-type thermoelectric element 244 are taken for illustration as shown in FIG. 2, functioning as a supporting plane to prevent the instable reliability of the solder layer. In practical applications, it is noted that the numbers of the strip-shaped spacers 284 could be determined based on the application conditions and the overall design requirements of the thermoelectric module for appropriate distribution, and the disclosure is not limited to the illustrated number presented in the embodiment.

In the thermoelectric module 200 of the embodiment, the strip-shaped spacers 284 could be metal wires or ceramic materials which are coated with metal layer, for example, nickel on the ceramic surface, while the metal electrode 216 could be a metal plate. Furthermore, the shapes of the metal electrodes 214 and 216 are not limit to flat, and other shapes are also applicable. Besides joining the metal electrodes with the strip-shaped spacers 284 in advance, the strip-shaped spacers 284 also could be connected with the solder layer and then joined with the metal electrodes simultaneously, followed by a reflow process to join each other.

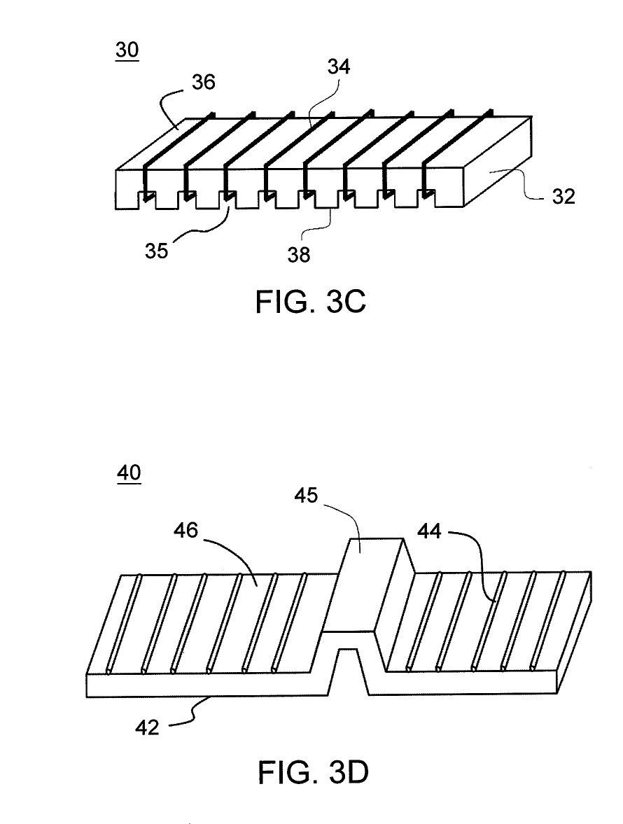

In the following description, several types of the strip-shaped spacers in the thermoelectric module are taken for illustration, but the disclosure is not limit thereto. Some of the combination types of the metal electrodes 216 and spacers 284 in FIG. 2 are shown in FIG. 3A to FIG. 3F. FIG. 3A to FIG. 3F are schematic views showing the first to the sixth combination type of the strip-shaped spacers in the thermoelectric module according to a first embodiment of the disclosure.

In FIG. 3A, combination 10 includes a metal plate 12 and a spacer 14 distributed on a surface 16 of the metal plate 12, wherein the spacer 14 contains a set of latitudinal-placed strip-shaped conductive elements 13 and a set of lengthwise-placed strip-shaped conductive elements 15 which cross to each other. Additionally, the spacer 14 may be a metal net. The material of the latitudinal-placed strip-shaped conductive elements 13 and the lengthwise-placed strip-shaped conductive elements 15 may be metal or ceramic with metallic surface. The latitudinal-placed strip-shaped conductive elements 13 and the lengthwise-placed strip-shaped conductive elements 15 may be fixed on the surface 16 of the metal plate 12 in advance by completely welding or partially welding or may be fixed between the metal plate 12 and thermoelectric elements (i.g. the P-type and the N-type thermoelectric elements 242, 244 as shown in FIG. 2) by utilizing the solder layer (i.g. the solder layer 222 shown in FIG. 2).

In FIG. 3B, combination 20 includes a metal plate 22 and a spacer 24 distributed on a surface 26 of the metal plate 22, wherein the spacer 24 includes a set of several latitudinal-placed strip-shaped conductive elements 23 and a set of several lengthwise-placed conductive elements 25 which are disposed on the latitudinal-placed strip-shaped conductive elements 23. Also, the material of the latitudinal-placed strip-shaped conductive elements may be metal or ceramic with metallic surface. The spacer 24 may be fixed on the surface 26 of the metal plate 22 in advance by completely welding or partially welding or may be fixed between the metal plate 12 and thermoelectric elements (i.g. the P-type and the N-type thermoelectric elements 242, 244 as shown in FIG. 2) by utilizing the solder layer (i.g. the solder layer 222 shown in FIG. 2).

In FIG. 3C, combination 30 includes a metal plate 32 and a strip-shaped conductive spacer 34 (i.g. a wire) wound on the surface of the metal plate 32. The upper surface 36 of the metal plate faces to the solder layer (i.g. the solder layer 222 as shown in FIG. 2) of the thermoelectric module and the strip-shaped conductive spacer 34 are disposed within the solder layer. After the thermoelectric module is assembled, the surface of the spacer 34 may selectively contact with the end surfaces of the thermoelectric elements. In FIG. 3C, there are several recesses 35 formed at the lower surface 38 of the metal plate 30 to make the winding intervals of the spacer 34 uniform and the lower surface 38 of the metal plate 30 be maintained as flatness.

In FIG. 3D, combination 40 includes a metal plate 42 and a spacer 44 distributed on the surface 46 of the metal plate 42, wherein the spacers 44 are several strip-shaped conductive elements. The material of the strip-shaped conductive elements may be metal or ceramic with metallic surface. Also, there is an inverse V-shaped (A) protrusion 45 in the middle of the metal plate 42 and its protruding direction faces the surface 46 of the metal plate. Alternatively, the protrusion 45 may be omega-shaped (Ω) or other shapes. After the thermoelectric module is assembled, the protrusion 45 points to the direction of the thermoelectric element. The spacer 44 may be fixed on the surface 46 of the metal plate 42 in advance by completely welding or partially welding. It is also applicable by using the solder layer (i.g. the solder layer 222 shown in FIG. 2) to fix the spacer 44 between the metal plate 42 and thermoelectric elements (i.g. the P-type and the N-type thermoelectric elements 242, 244 as shown in FIG. 2).

In FIG. 3E, combination 50 includes a metal plate 52 and a spacer 54 distributed on the surface 56 of the metal plate 52, wherein the spacers 54 are several strip-shaped conductive elements. The material of the strip-shaped conductive elements may be metal or ceramic with metallic surface. Furthermore, there are several cone-shaped protrusions 55 formed on the upper surface 56 of the metal plate 52. The cone-shaped protrusions 55 emboss the metal plate, for example, by stamping. The cone-shaped protrusions 55 facilitate the setting and positioning of the spacers 54, and also reinforce the thickness of the solder layer. Although the cone-shaped protrusions 55 of the metal plate in FIG. 3E are taken for illustration, the shape is not limit thereto. The shapes of the protrusions may be conical, pyramidal, cylindrical, corner column-shaped, ball-shaped, ellipsoidal, or other shapes for providing the similar effects as the cone-shaped protrusions 55.

In FIG. 3F, combination 60 includes a metal plate 62 and a spacer 64 distributed on the surface 66 of the metal plate 62, wherein the spacers 64 are several strip-shaped conductive elements. The material of the strip-shaped conductive elements may be metal or ceramic with metallic surface. The metal plate 62 is a stack containing an upper plate 61, a lower plate 65 and a solder layer 63 sandwiched between the two metal plates 61 and 65, wherein the melting point of the solder layer 63 is lower than that of the two metal plates 61 and 65. The thermal stress of the thermoelectric module in operation may be decreased to improve the work life of the thermoelectric module, by utilizing the metal plates 61 and 65 with the solder layer 63 having lower melting point disposed there between as a metal electrode. Although the metal plate 62 of the combination 60 as illustrated in FIG. 3F is a two-layer structure, the metal plate with the multilayer structure with more than two layers would also have the same effects. Therefore, the types of the metal plates are not limited to the two-layer structure as shown in FIG. 3F.

### Second Embodiment

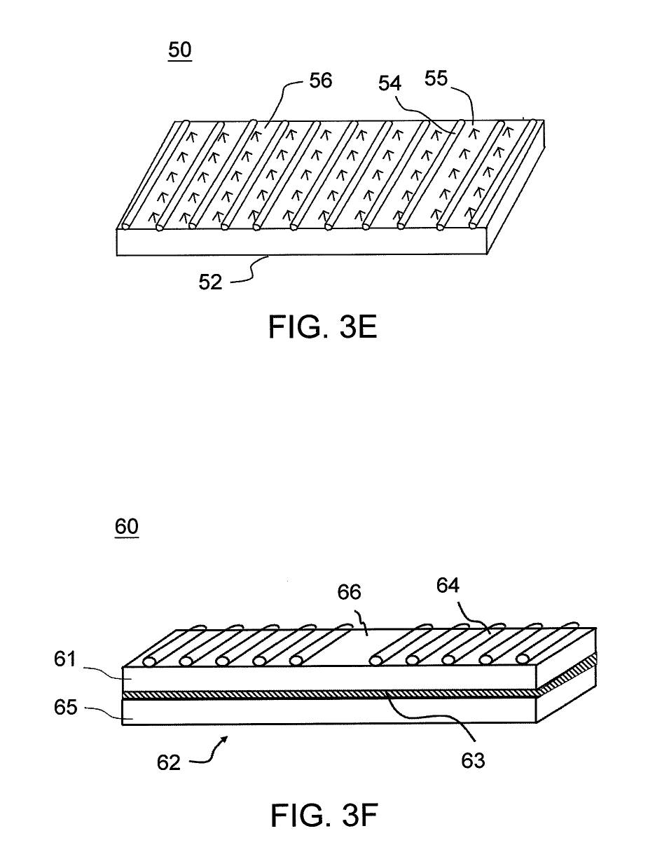

FIG. 4 is a schematic view showing a thermoelectric module according to a second embodiment of the disclosure. The difference between the first embodiment and the second embodiment is that the spacers of the thermoelectric module 300 of the second embodiment are granulated spacers 384. Moreover, the several P-type segmented thermoelectric elements 342 and N-type segmented thermoelectric elements 344 are arranged alternately, and each of the P-type segmented thermoelectric elements 342 and N-type segmented thermoelectric elements 344 are joined by the thermoelectric elements denoted as P1 and P2, and the thermoelectric elements denoted as N1 and N2 in the thermoelectric module 300, respectively.

In FIG. 4, the thermoelectric module 300 includes a first substrate 311 and a second substrate 312 which are disposed to each other. The thermoelectric module 300 also includes several P-type segmented thermoelectric elements 342, N-type segmented thermoelectric elements 344, the first metal electrodes 314, the second metal electrodes 316, the first solder layers 321, the second solder layer 322 and granulated spacers 384.

Several pairs of the thermoelectric elements 340 are disposed between the first substrate 311 and the second substrate 312. Each pair of the thermoelectric elements 340 include a P-type segmented thermoelectric element 342 and a N-type segmented thermoelectric element 344 which are connected to each other electrically. The N-type segmented thermoelectric element 344 and the P-type segmented thermoelectric element 342 of each pair of the thermoelectric elements are connected to each other electrically. The several first metal electrodes 314 are disposed between the first substrate 311 and the lower end surfaces (such as exothermic end) of the P-type segmented thermoelectric element 342 and the N-type segmented thermoelectric element 344. The first metal electrodes 314 are connected to each pair of the P-type segmented thermoelectric element 342 and the N-type segmented thermoelectric element 344, respectively. The several second metal electrodes 316 are disposed between the second substrate 312 and the upper end surfaces (such as endothermic end) of the P-type segmented thermoelectric element 342 and the N-type segmented thermoelectric element 344. The second metal electrodes 316 are connected to the P-type segmented thermoelectric element 342 and the N-type segmented thermoelectric element 344 of adjacent two pairs of the thermoelectric element, a P-type segmented thermoelectric element 342 and a N-type segmented thermoelectric element 344 of a pair of thermoelectric element 340 which is adjacent to the P-type segmented thermoelectric element 342, and a N-type segmented thermoelectric element 344 and a P-type segmented thermoelectric element 342 of a pair of thermoelectric element 340 which is adjacent to the a N-type segmented thermoelectric element 344 to make the P-type segmented thermoelectric elements 342 and the N-type segmented thermoelectric elements 344 described above be connected to each other electrically.

Moreover, the first solder layers 321 are connected to the first metal electrodes 314 and the lower end surfaces of the P-type segmented thermoelectric elements 342 and the N-type segmented thermoelectric elements 344. The second solder layers 322 are connected to the second metal electrodes 316 and the upper end surfaces of the P-type segmented thermoelectric elements 342 and the N-type segmented thermoelectric elements 344.

In an embodiment, the granulated spacers 384 are distributed in the first solder layers 321 and the second solder layers 322. The melting point of the granulated spacers 384 are higher than the liquidus temperature of alloy material of the first and second solder layers 321 and 322. The shape of the granulated spacers 384 may be small particles with spherical, ellipsoid, cubic or other irregular shapes.

In an embodiment, an average diameter of the granulated spacers 384 is in a range of about 30% to about 100% of the thicknesses of the first and second solder layers 321 and 322. In another embodiment, an average diameter of the granulated spacers 384 is in a range of about 30% to about 60% of the thicknesses of the first and second solder layers 321 and 322. In an embodiment, an average diameter of the granulated spacers 384 is in a range of about 15 μm to about 300 μm. In another embodiment, an average diameter of the granulated spacers 384 is in a range of about 15 μm to about 100 μm. In an embodiment, the ratio of the length to the diameter of the granulated spacers 384 is about 1 to 10. Furthermore, the sizes the granulated spacers 384 of the embodiment may be substantially the same or different. Although the sizes of the granulated spacers 384 shown in FIG. 4 are substantially the same, in an embodiment, the granulated spacers also may include the first and the second spacers which have at least two different sizes.

Moreover, although the granulated spacers 384 are disposed in the first and second solder layers 321 and 322 in FIG. 4, the disclosure is not limit thereto. If the granulated spacers 384 are disposed on one of the first or the second solder layers 321 and 322, there still have the great effects of supporting thermoelectric module.

In the embodiment, the first and the second metal electrodes 314 and 316 are pure metal plates, or alloy plates. In an embodiment, the material of the granulated spacers 384 such as grains of pure metal or alloy is selected from the group consisting of iron, cobalt, nickel, chromium, copper, manganese, zirconium, titanium and a combination thereof so as to form intermetallic compounds with liquid tin. The surfaces of the granulated spacers 384 also may be coated with nickel, silver or tin selectively for facilitating the soldering effect. Examples of the first and the second solder layers 321 and 322 are tin alloy layers.

Furthermore, in an embodiment, the granulated spacers 384 may be connected with the first and the second metal electrodes 314 and 316 by welding or electroplating, then a stacked Sn/Ni/Sn layer (not shown) is coated on the joining (inner) surface of the metal electrodes to facilitate the connection between the inner surfaces of the metal electrodes and the first and the second solder layers 321 and 322.

In the embodiment, since the outer surfaces of the first and the second metal electrodes 314 and 316 are naked metal surfaces 314a and 316a. In order to protect electrical series circuit of the thermoelectric module 300, the first substrate 311 and the second substrate 312 may be, for example, a high conductivity and insulation sheeting material respectively are covered on the naked metal surfaces 314a and 316a described above. Besides use of the high conductivity and insulation sheeting material, in another embodiment, the metal naked surface 314a and 316a of the first and the second metal electrodes 314 and 316 could be respectively coated by an insulation layer.

In the embodiment, the first and the second solder layers 321 and 322 may be, for example, tin alloy layer. In another embodiment, the first and the second solder layers 321 and 322 also may be a multi-layer solder such as stacked tin sheets and stacked nickel sheets, or tin sheets and stacked silver sheets.

The thermoelectric module 300 provided in the embodiment as shown in FIG. 4 may control the original interface joining thickness T of the first and the second solder layers by the existence of the granulated spacers 384 described above. The thicker the interface joining thickness T is, the easier the thermal stress of the thermoelectric module 300 in operation be adjusted to prevent relatively brittle thermoelectric elements from being broken. The thermoelectric module 300 in over-temperature operation, even the solder layer on the upper end of the P-type and N-type thermoelectric elements occur fusion, the thickness of the solder layer still may be maintained to prevent a lot of fusion solder liquid be squeezed out of the welding surface to improve the operation reliability of the thermoelectric module 300 in the supporting effects of the strip-shaped spacers 384. In other words, when the thermoelectric module 300 is operated in severe temperature condition, the diameter of the strip-shaped spacers 384 determine the possible minimum distance between the first and the second solder layers 321 and 322, and the P-type and N-type thermoelectric elements.

Besides welding or electroplating, the combination of the granulated spacers 384 and the first and the second metal electrodes 314 and 316 may also be processed by mixing the granulated spacers uniformly in a paste solder, then the paste solder with granulated spacers is coated on the metal electrode and metallized as being the solder layers by reflow process.

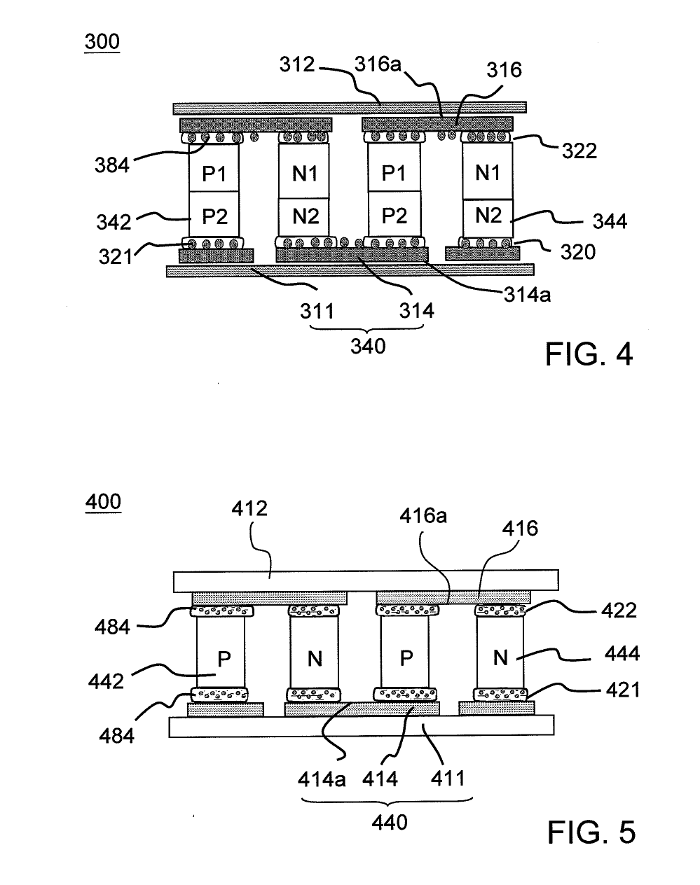

FIG. 5 is a schematic view showing another thermoelectric module according to a second embodiment of the disclosure.

Similarly, the thermoelectric module 400 provided in FIG. 5 includes the first substrate 411 and the second substrate 412 which are disposed to each other, several P-type thermoelectric elements 442, N-type thermoelectric elements 444, several the first metal electrodes 414, several the second metal electrodes 416, several the first solder layers 421, several the second solder layers 422 and the granulated spacers 484 distributed randomly in the solder layers.

In FIG. 5, each pair of the thermoelectric element 440 include a P-type thermoelectric element 442 and a N-type thermoelectric element 444 which are electrically connected to each other by the first metal electrode 414 (disposed between the first substrate 411 and the lower end surfaces of the P-type thermoelectric element 442 and the N-type thermoelectric element 444). The N-type thermoelectric elements 444 of each pair of the thermoelectric elements are electrically connected to another adjacent P-type thermoelectric element 442 of each pair of the thermoelectric elements by the second electrode 416 (disposed between the second substrate 412 and the upper end surfaces of the P-type thermoelectric element 442 and the N-type thermoelectric element 444).

In FIG. 5, the first substrate 411 and the second substrate 412, for example, are a ceramic plate and a high conductivity and insulation sheeting material, respectively. The metal layer is joined on the ceramic plate. The ceramic plate and the first metal electrode joined on the surface of the ceramic plate (the first substrate 411) are generally called direct covered metal ceramic plate. In the embodiment, the surfaces 414a and 416a of the first metal electrodes 416 and the second metal electrodes 416 pointing to the first solder layer 421 and the second solder layer 422 which may be coated with nickel, silver or tin selectively as helping welding layer to improve wettability between the solder layers and the metal electrodes to promote the welding effects there between.

The positions, material and other related content of the other parts may be referred to the content described above and not described repeatedly.

In actual manufacturing, the granulated spacers 484, such as nickel particles or small pieces of nickel wire, may be mixed with the paste material of the solder in advance, then coated on the surfaces of the first metal electrodes 414 and the second metal electrodes 416. The interface of the first and the second metal electrodes 414 and 416, and interface of the P-type thermoelectric element 442 and the N-type thermoelectric element 444 are joined by reflow heating. Alternatively, the solder paste could be firstly coated on the surfaces of the first metal electrodes 414 and the second metal electrodes 416, and the small pieces of nickel wires or grains are then disposed on the solder paste described above. The reflow process is proceeded finally and the thermoelectric module 400 is assembled. In an embodiment, the granulated spacers 484 occupy in a range of about 5 volume percent to about 50 volume percent of the solder, for example, about 10 volume percent or other range of volume percent.

Several applications of the granulated spacers in the thermoelectric module of the second embodiment are described as below, but they do not intend to limit the disclosure.

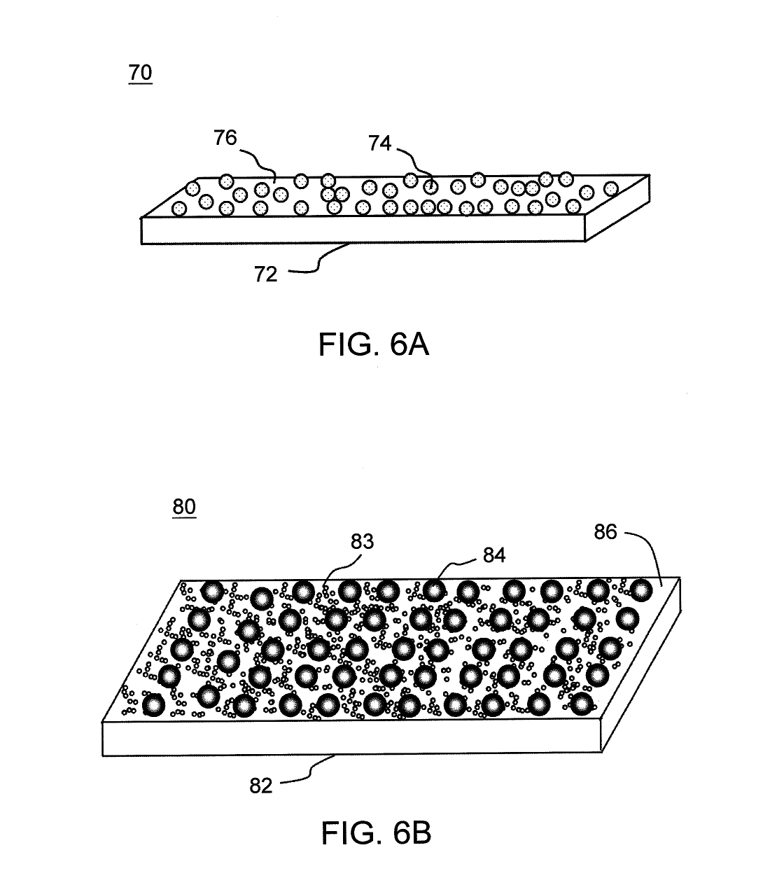

Please refer to the FIG. 6A, it is a schematic view showing a combination type of the granulated spacers and the metal electrodes of the thermoelectric module according to a second embodiment of the disclosure. As shown in FIG. 6A, combination 70 includes a metal plate 72 and granulated spacers 74 distributed on a surface 76 of the metal plate 72, wherein the granulated spacers 74 are spherical conductors. The material of the granulated spacers 74 may be metal such as nickel, or be ceramic with metallic surface, for example nickel plating. Although the shape of the spacers 74 in FIG. 6A is spherical, other shapes of the grains also have the similar supporting effects and could be applied in the disclosure. The granulated spacers 74 in FIG. 6A may be fixed on the surface 76 of the metal plate 72 by partially spot welding. The granulated spacers 74 also may be fixed between the metal plate 72 and the thermoelectric elements (such as the thermoelectric elements 442 and 444 in FIG. 4) by utilizing the solder layers (such as the first and the second solder layers 321 and 322 in FIG. 4).

Please refer to the FIG. 6B, it is a schematic view showing another combination type of the granulated spacers and the metal electrodes of the thermoelectric module according to a second embodiment of the disclosure. As shown in FIG. 6B, combination 80 includes a metal plate 82 and granulated spacers 83 and 84 distributed on a surface 86 of the metal plate 82, wherein the granulated spacers 83 and 84 are spherical conductors with two different sizes. The material of the granulated spacers 83 and 84 may be metal or ceramic with metallic surface. In the embodiment, the granulated spacers 83 and 84 may be fixed on the surface 86 of the metal plate 82 by partially spot welding. The granulated spacers 83 and 84 also may be fixed between the metal plate 82 and the thermoelectric elements (such as the thermoelectric elements 442 and 444 in FIG. 4) by utilizing the solder layers (such as the first and the second solder layers 321 and 322 in FIG. 4). Although the grains with only two different sizes are shown in FIG. 6B, the grains which have more than two different sizes are also applicable in alternative embodiments. Furthermore, besides by spot welding, particles with different sizes also may be formed on the metal layer by coating. For example, it is one of the applications that the bigger spacers 84 are fixed on the surfaces 86 of the metal plate 82 by spot welding in advance, and the solder material with the smaller spacers 83 is then coated on the surfaces 86 of the metal plate 82.

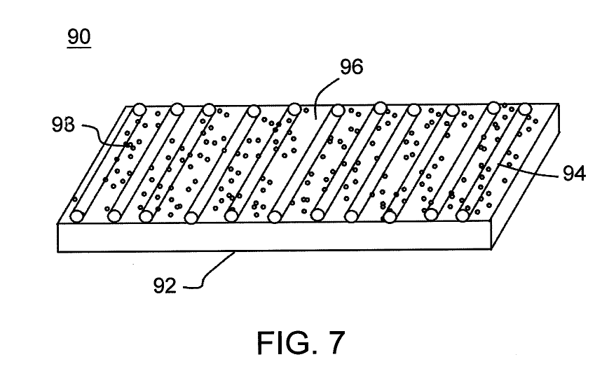

In the first and second embodiments, the strip-shaped spacers and the granulated spacers are respectively taken for illustrating the supporting effect of the spacers of the disclosure. In practical applications, the spacers having different shapes such as a combination of the granulated and strip-shaped spacers also have the same supporting effects as the embodiments described above. FIG. 7 is a schematic view showing a combination type of the spacers and the metal electrodes of the thermoelectric module according to another embodiment of the disclosure. As shown in FIG. 7, combination 90 includes a metal plate 92 and spacers 93 and 94 distributed on a surface 96 of the metal plate 92, wherein the spacers 93 are granulated conductive elements while the spacers 94 are a set of the strip-shaped conductive elements. The material of the granulated and the strip-shaped conductive elements (spacers 93 and 94) may be metal or ceramic with metallic surface. Practically, both of the spacers 93 and 94 could be fixed on the surface 96 of the metal plate 92 by partially spot welding, or could be fixed between the metal plate 92 and the thermoelectric element by utilizing the solder layer of the thermoelectric module. Alternatively, the strip-shaped conductive elements (spacer 94) could be fixed on the metal plate 92 by the combination of welding and coating, and the solder material mixed with the grain conductive elements (spacer 93) is then coated on the surfaces 96 of the metal plate 92 for distribution of the spacer 93.

To sum up, the thermoelectric module having the solder layers with stable thickness is provided in the embodiments, wherein the spacers (such as the strip-shaped, the grain or a combination thereof) are disposed between the metal electrodes and electrical series of the P-type or N-type thermoelectric element. The melting point of the spacers is higher than the liquidus temperature of solder layer to maintain the minimum solder layer thickness between the metal electrodes and the thermoelectric elements to improve the operation reliability and extend the working life of the thermoelectric module.

While the disclosure has been described by way of example and in terms of the preferred embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A thermoelectric module, comprising:
a first substrate and a second substrate disposed opposite to each other;
a plurality of P-type and N-type thermoelectric elements, each of the thermoelectric elements having an upper end surface and a lower end surface and disposed alternately between the first substrate and the second substrate;
a plurality of first metal electrodes disposed between the first substrate and the lower end surfaces of the P-type and the N-type thermoelectric elements for electrically connecting to each of the thermoelectric elements respectively or electrically connecting to the adjacent P-type thermoelectric element and the N-type thermoelectric element;
a plurality of first solder layers for joining the first metal electrodes and the lower end surfaces of the P-type and the N-type thermoelectric elements respectively;
a plurality of second metal electrodes disposed between the second substrate and the upper end surfaces of the P-type and the N-type thermoelectric elements for electrically connecting to each of the thermoelectric elements or electrically connecting to the adjacent P-type thermoelectric element and the N-type thermoelectric elements respectively;
a plurality of second solder layers for joining the second metal electrodes and the upper end surfaces of the P-type and the N-type thermoelectric elements respectively; and
a spacer at least disposed at and contacting one of the first solder layers and the second solder layers, the melting point of the spacer higher than the liquidus temperature of at least one of the first solder layers and the second solder layers contacting the spacer.

2. The thermoelectric module according to claim 1, wherein the spacer comprises a plurality of strip-shaped spacers.

3. The thermoelectric module according to claim 2, wherein the strip-shaped spacers are disposed on at least one of the surfaces of the first metal electrodes and the second metal electrodes, and the strip-shaped spacers are disposed correspondingly within one of the first solder layers and the second solder layers.

4. The thermoelectric module according to claim 2, wherein the strip-shaped spacers are disposed on at least one of the surfaces of the first metal electrodes and the second metal electrodes, part of the strip-shaped spacers are disposed correspondingly within one of the first solder layers and the second solder layers, and part of the strip-shaped spacers are exposed outside the corresponding first or the second solder layers.

5. The thermoelectric module according to claim 3, wherein the strip-shaped spacers contact at least one of the upper end surfaces and the lower end surfaces of the P-type and the N-type thermoelectric elements.

6. The thermoelectric module according to claim 5, wherein the part of the strip-shaped spacers for contacting the upper end surfaces and the lower end surfaces of the P-type and the N-type thermoelectric elements is exposed outside the first or the second solder layers.

7. The thermoelectric module according to claim 2, wherein the height of the strip-shaped spacers is in a range of about 50% to about 100% of the thickness of the first or the second solder layers which the strip-shaped spacers are disposed in.

8. The thermoelectric module according to claim 2, wherein the height of the strip-shaped spacers is in a range of about 15 μm to about 500 μm.

9. The thermoelectric module according to claim 1, wherein the spacer comprises a plurality of granulated spacers.

10. The thermoelectric module according to claim 9, wherein the granulated spacers are embedded in at least one of the first solder layers and the second solder layers.

11. The thermoelectric module according to claim 9, wherein the granulated spacers are dispersed within at least one of the first solder layers and the second solder layers.

12. The thermoelectric module according to claim 9, wherein the diameter of the granulated spacers is in a range of about 30% to about 100% of the thickness of the first or the second solder layers which the granulated spacers are disposed in.

13. The thermoelectric module according to claim 9, wherein the diameter of the granulated spacers is in a range of about 15 μm to about 300 μm.

14. The thermoelectric module according to claim 9, wherein a ratio of the length of the granulated spacers to the diameter of the granulated spacers is in a range of about 1 to about 10.

15. The thermoelectric module according to claim 9, wherein the granulated spacers comprise at least two different sizes of a plurality of first and second support particles.

16. The thermoelectric module according to claim 1, wherein the spacer comprises a combination of a plurality of strip-shaped spacers and a plurality of granulated spacers.

17. The thermoelectric module according to claim 1, wherein the material of the spacer is metal or ceramic with metallized surface.

18. The thermoelectric module according to claim 1, wherein the material of the spacer is selected from the group consisting of iron, cobalt, nickel, chromium, copper, manganese, zirconium, titanium and a combination thereof.

19. A method of manufacturing a thermoelectric module, comprising:
providing a first substrate, a second substrate, a plurality of P-type thermoelectric elements and a plurality of N-type thermoelectric elements, each of the thermoelectric elements having an upper end surface and a lower end surface;
providing a plurality of first and second metal electrodes, a surface of one of the end surfaces of at least one of the first and the second metal electrodes having a spacer, the one of the end surfaces pointing to the thermoelectric elements;
disposing the first and the second metal electrodes between the first substrate and the second substrate, disposing the P-type and N-type thermoelectric elements alternately and between the first and the second metal electrodes, connecting to the lower faces of the thermoelectric elements by the first metal electrodes while connecting the upper faces of the thermoelectric elements by the second metal electrodes;
providing a plurality of first solder plates on the surfaces of the first metal electrodes and providing a plurality of the second solder plates on the surfaces of the second metal electrodes, the spacer contacting at least one solder plate of the first and the second solder plates wherein the melting point of the spacer higher than the liquidus temperature of the first and the second solder plates; and
assembling the first substrate, the first metal electrodes, the P-type thermoelectric elements, the N-type thermoelectric elements, the second metal electrodes and the second substrate to make the first solder plates form the first solder layers and join the first metal electrodes and a plurality of lower end surfaces of the P-type and the N-type thermoelectric elements, and to make the second solder plates form the second solder layers and join the second metal electrodes and a plurality of upper end surfaces of the P-type and the N-type thermoelectric elements.

20. The method of manufacturing the thermoelectric module according to claim 19, wherein the spacer is a plurality of strip-shaped spacers and at least one solder layer of the first and the second solder layers has the strip-shaped spacers.

21. The method of manufacturing the thermoelectric module according to claim 20, wherein the strip-shaped spacers are formed on the surfaces of the first and the second metal electrodes by soldering, electroplating, coating, twining or a combination thereof.

22. The method of manufacturing the thermoelectric module according to claim 20, wherein a surface of one of the end surfaces of at least one of the first and the second metal electrodes has a plurality of recesses for fixing the strip-shaped spacers and the one of the end surfaces is back to the thermoelectric elements.

23. The method of manufacturing the thermoelectric module according to claim 20, wherein the height of the strip-shaped spacers is in a range of about 50% to about 100% of the thickness of the first or the second solder layers which the strip-shaped spacers are disposed in.

24. The method of manufacturing the thermoelectric module according to claim 20, wherein the height of the strip-shaped spacers is in a range of about 15 μm to about 500 μm.

25. The method of manufacturing the thermoelectric module according to claim 19, wherein the spacer is a plurality of granulated spacers and at least one solder layer of the first and the second solder layers has the granulated spacers.

26. The method of manufacturing the thermoelectric module according to claim 25, wherein the granulated spacers are formed on the surfaces of the first and the second metal electrodes by soldering, electroplating, coating, or a combination thereof.

27. The method of manufacturing the thermoelectric module according to claim 25, wherein the diameter of the granulated spacers is in a range of about 30% to about 100% of the thickness of the first or the second solder layers which the granulated spacers are disposed in.

28. The method of manufacturing the thermoelectric module according to claim 25, wherein the diameter of the granulated spacers is about 15 μm to about 300 μm.

29. The method of manufacturing the thermoelectric module according to claim 25, wherein the ratio of the length of the granulated spacers to the diameter of the granulated spacers is between about 1 to about 10.

30. The method of manufacturing the thermoelectric module according to claim 25, wherein the granulated spacers comprise at least two different sizes of a plurality of first and second support particles.

31. A method of manufacturing a thermoelectric module, comprising:
providing a first substrate, a second substrate, a plurality of P-type thermoelectric elements and a plurality of N-type thermoelectric elements, each of the thermoelectric elements having an upper end surface and a lower end surface, a plurality of first and second metal electrodes, a paste solder and a plurality of granulated spacers, the melting point of the granulated spacers higher than the liquidus temperature of the metallized solder;
mixing the granulated spacers with the paste solder;
coating the paste solder mixed with the granulated spacers on the surface of at least one of the first and/or the second metal electrodes, in order to form a plurality of first solder layers on the first metal electrodes and to form a plurality of second solder layers on the second metal electrodes after an reflow assembly;
disposing the first and the second metal electrodes between the first substrate and the second substrate, disposing the P-type and N-type thermoelectric elements alternately and between the first and the second metal electrodes, connecting to the lower faces of the thermoelectric elements by the first metal electrodes while connecting to the upper faces of the thermoelectric elements by the second metal electrodes; and
reflow assembling the first substrate, the first metal electrodes, the P-type thermoelectric elements, the N-type thermoelectric elements, the second metal electrodes and the second substrate to make the first solder layers spread the granulated spacers therein join the first metal electrodes and the lower end surfaces of the P-type and the N-type thermoelectric elements, and/or to make the second solder layers spread the granulated spacers therein join the second metal electrodes and the upper end surfaces of the P-type and the N-type thermoelectric elements.

32. The method of manufacturing the thermoelectric module according to claim 31, wherein the granulated spacers occupy in a range of about 5 volume percent to about 50 volume percent of the solder.

33. The method of manufacturing the thermoelectric module according to claim 31, wherein the diameter of the granulated spacers is in a range of about 30% to about 100% of the thickness of the first or the second solder layers which the granulated spacers are disposed in.

34. The method of manufacturing the thermoelectric module according to claim 31, wherein the diameter of the granulated spacers is in a range of about 15 μm to about 300 μm.

35. The method of manufacturing the thermoelectric module according to claim 31, wherein the ratio of the length of the granulated spacers to the diameter of the granulated spacers is in a range of about 1 to about 10.

36. The method of manufacturing the thermoelectric module according to claim 31, wherein the granulated spacers comprise at least two different sizes of a plurality of first and second support particles.
